(19) United States
(12) Patent Application Publication
(10) Pub. No.: US 2017/0094840 A1
(43) Pub. Date: Mar. 30, 2017

(54) CONTROL SYSTEM AND METHOD FOR CONTROLLING SERVER

(71) Applicant: HON HAI PRECISION INDUSTRY CO., LTD., New Taipei (TW)

(72) Inventor: YU-CHEN HUANG, New Taipei (TW)

(21) Appl. No.: 14/886,830

(22) Filed: Oct. 19, 2015

(30) Foreign Application Priority Data
Sep. 24, 2015 (TW) 104131609

(51) Int. Cl. H05K 7/20; G05B 15/02

(52) U.S. Cl. CPC H05K 7/20836; G05B 15/02

(57) ABSTRACT

The disclosure control system for a server provides a battery, a power supply is configured for providing power to a server system, a temperature sensor is configured for sensing a temperature in the server system; a BMC is configured for obtaining the temperature from the temperature sensor; and a warning module is configured for outputting warning information. A control method is also provided.

### FIELD

The subject matter herein generally relates to a control system and method for controlling a server.

### BACKGROUND

Generally, the baseboard management controller (BMC) is configured for monitoring the operation states of a server system. The BMC is powered by a power supply.

### BRIEF DESCRIPTION OF THE DRAWINGS

Implementations of the present technology will now be described, by way of example only, with reference to the attached figures.

FIG. 1 is a block diagram of an example embodiment of a control system of the present disclosure.

FIG. 2 is a flow chart of an example embodiment of a control method of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

A definition that applies throughout this disclosure will now be presented.

The term “comprising” means “including, but not necessarily limited to”; it specifically indicates open-ended inclusion or membership in a so-described combination, group, series and the like.

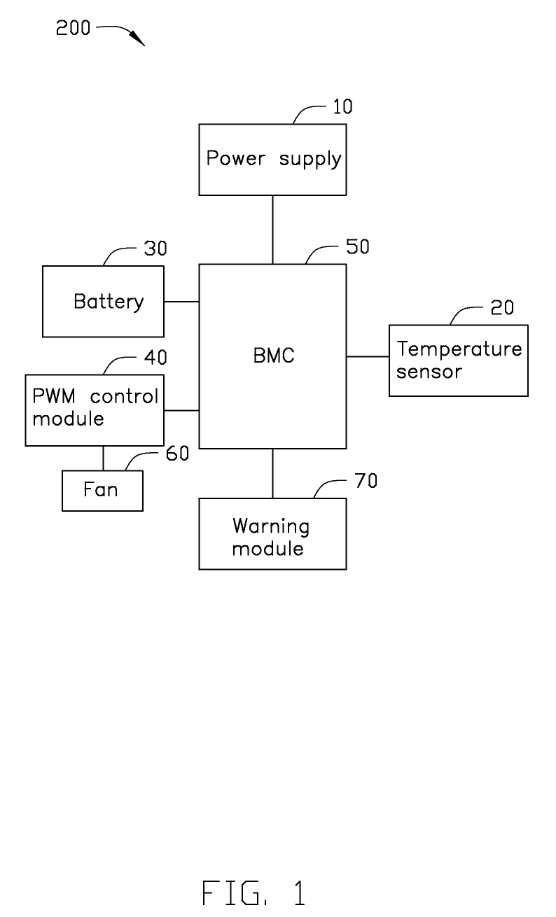

FIG. 1 illustrates control system 200 for a server of the present disclosure. The control system in accordance with an exemplary embodiment can comprise a power supply 10, a temperature sensor 20, a battery 30, a pulse width modulation (PWM) control module 40, a baseboard management controller (BMC) 50, a fan 60, and a warning module 70.

In the illustrated embodiment, the power supply 10 can be installed inside of a system (such as a server system) to provide power to the server system. The temperature sensor 20 can be installed in the server system to sense the temperature in the server system. The battery 30 can be installed in the server system to provide power to the BMC 50. The PWM control module 40 can be installed in the server system to control the operation states of a fan 60, and the fan operation states include turning off the fan, and adjusting the fan speed when the fan is turned on. In the illustrated embodiment, the BMC 50 controls the PWM control module 40 to output a pulse signal to the fan 60, to adjust the speed of the fan 60.

In the illustrated embodiment, the BMC 50 is electrically coupled to each power supply 10, the temperature sensor 20, the battery 30, the PWM control module 40, and the warning module 70. The BMC 50 can be installed in the server system to detect the operation states of the power supply 10, and to obtain the temperature in the computer system sensed by the temperature sensor 20.

In the illustrated embodiment, the BMC 50 is configured for setting a preset temperature, and comparing the temperature transmitted by the temperature sensor 20 with the preset temperature. When the temperature transmitted by the temperature sensor 20 is higher than the preset temperature, if the temperature of the server system is abnormal.

In the illustrated embodiment, the BMC 50 detects when the power supply 10 is not supplying the server system, the battery 30 provides power to the BMC 50.

In the illustrated embodiment, the BMC 50 detects when the power supply 10 is supplying the server system, the BMC 50 is normal operation and monitoring the operation states of the system (such as temperature and fan speed of the system).

In operation, the BMC 50 starts to detect the operation states of the power supply 10. When the power supply 10 is supplying power to the system, the BMC 50 monitors the operation states of the system. For example, when the temperature of the system obtained by the BMC 50 is higher than the preset temperature, the BMC 50 outputs a control signal to the PWM control module 40, the PWM control module 40 adjusts the ratio of the duty cycle of the pulse signal according to the control signal, to adjust the speed of the fan 60.

The BMC 50 detects when the power supply 10 does not supply power to the server system, the battery 30 starts to provide power to the BMC 50. In the meantime, the BMC 50 works in a low power consumption mode, and reduces power consumption automatically. For example, the BMC 50 will not monitor the operation states of the fan 60, and reduces the frequency of a memory and a central processing unit (CPU) of the BMC 50. In the meantime, the BMC 50 monitors the temperature of the system, and obtains the temperature of the system from the temperature sensor 20. When the temperature of the system obtained by the BMC 50 is higher than the preset temperature, the BMC 50 outputs a first warning signal to the warning module 70. The warning module 70 obtains the first warning signal from the BMC 50, and outputs first warning information. When the temperature of the system obtained by the BMC 50 is lower than the preset temperature, the BMC 50 outputs a second warning signal to the warning module 70. The warning module 70 obtains the second warning signal from the BMC 50, and outputs second warning information.

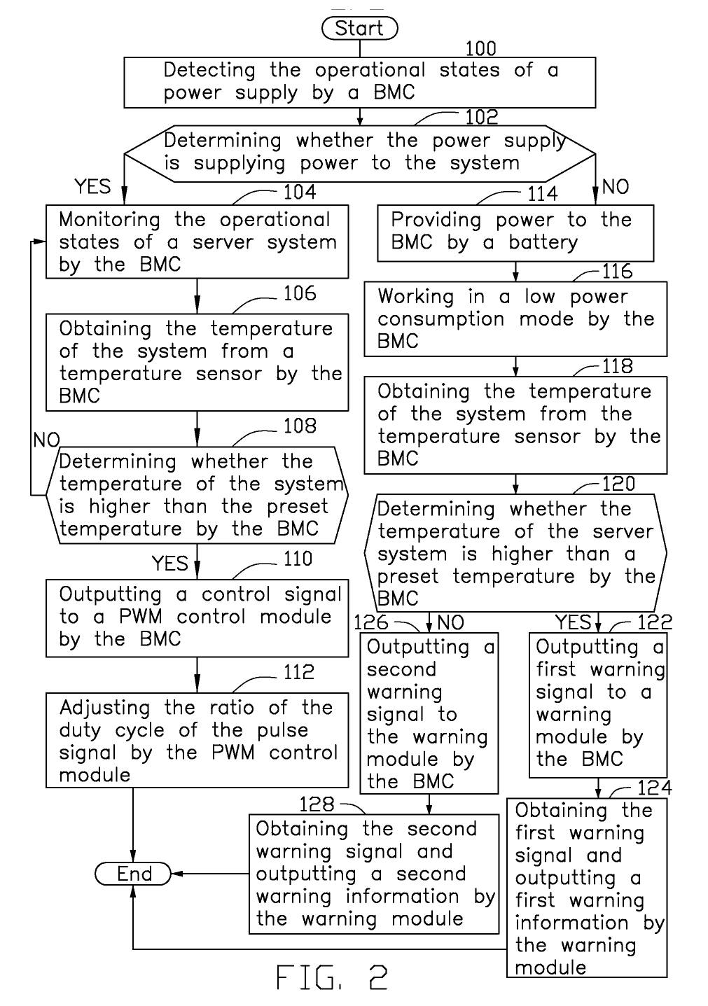

Referring to FIG. 2, a flowchart is presented in accordance with an example embodiment which is being thus illustrated. The example method is provided by way of example, as there are a variety of ways to carry out the method. The method described below can be carried out using the configurations illustrated in FIG. 1, for example, and various elements of these figures are referenced in explaining example method. Block shown in FIG. 2 represents one or more processes, methods, or subroutines, carried out in the test method. Furthermore, the illustrated order of blocks is by example only and the order of the blocks can change. Additional blocks may be added or fewer blocks may be utilized, without departing from this disclosure. The control method for a server can begin at block 100.

At block 100, a BMC 50 starts to detect the operation states of a power supply 10.

At block 102, the BMC 50 determines whether the power supply 10 is supplying power to the system. If the BMC 50 detects the power supply 10 is supplying power to the system, block 104 is implemented, and otherwise block 114 is implemented.

At block 104, the BMC 50 monitors the operation states of the system, such as the temperature and the speed of the fan of the system.

At block 106, the BMC 50 obtains the temperature of the system from the temperature sensor 20, and compares the temperature of the system transmitted by the temperature sensor 20 with the preset temperature.

At block 108, the BMC 50 determines whether the temperature of the sever system is higher than the preset temperature. If the temperature of the system obtained by the BMC 50 is higher than the preset temperature, block 110 is implemented, otherwise returns to block 104.

At block 110, the BMC 50 outputs a control signal to the PWM control module 40.

At block 112, the PWM control module 40 obtains the control signal from the BMC 50 and adjusts the ratio of the duty cycle of the pulse signal according to the control signal, to adjust the speed of the fan 60.

At block 114, the battery 30 starts to provide power to the BMC 50.

At block 116, the BMC 50 works in a low power consumption mode, and reduces power consumption automatically. For example, the BMC 50 will not monitor the operation states of a fan 60, and reduces the frequency of a memory and a CPU of the BMC 50.

At block 118, the BMC 50 obtains the temperature of the system from the temperature sensor 20, and compares the temperature of the system transmitted by the temperature sensor 20 with the preset temperature, and obtains a result of comparison.

At block 120, the BMC 50 determines whether the temperature of the sever system is higher than the preset temperature. If the temperature of the system obtained by the BMC 50 is higher than the preset temperature, block 122 is implemented, otherwise block 126 is implemented.

At block 122, the BMC 50 outputs a first warning signal to the warning module 70.

At block 124, the warning module 70 obtains the first warning signal from the BMC 50, and outputs first warning information.

At block 126, the BMC 50 outputs a second warning signal to the warning module 70.

At block 128, the warning module 70 obtains the second warning signal from the BMC 50, and outputs second warning information.

While the disclosure has been described by way of example and in terms of a preferred embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A control system comprising:
a battery;
a power supply coupled to the battery and configured to provide power to a server system;
a temperature sensor configured to sense a temperature of the server system;
a baseboard management controller (BMC) coupled to the temperature sensor and configured for setting a preset temperature, the BMC configured to detect an operation state of the power supply, the BMC obtain the temperature of the system from the temperature sensor, and compare the temperature of the system transmitted by the temperature sensor with the preset temperature; and
a warning module coupled to the BMC;
wherein when the power supply leaves off power for the server system, the battery provides power to the BMC;
wherein when the temperature of the system obtained by the BMC is higher than the preset temperature, the BMC outputs a first warning signal to the warning module and when the temperature of the system obtained by the BMC is low than the preset temperature, the BMC outputs a second warning signal to the warning module; and
wherein the warning module is configured to output a first warning information and a second warning information corresponding to the first warning signal and the second signal transmitted by the BMC.

2. The control system of claim 1, wherein the control system comprises a pulse width modulation (PWM) and a fan, both the BMC and the fan are electrically coupled to the PWM, the BMC controls the operation states of the fan through the PWM.

3. The control system of claim 2, wherein when the power supply provides power to the server system and the temperature of the system obtained by the BMC is higher than the preset temperature, the BMC outputs a control signal to the PWM control module, the PWM control module obtains the control signal and adjusts the speed of the fan according to the control signal transmitted by the BMC.

4. The control system of claim 3, wherein the PWM control module adjusts the ratio of the duty cycle of a pulse signal to the fan to adjust the speed of the fan according to the control signal transmitted by the BMC.

5. A control method comprising:
detecting a operation states of a power supply by a basic management controller (BMC), and supplying power to the BMC by a battery when the power supply leaves off power supply for a server system;
sensing the temperature in the server system by a temperature sensor, and transmitting the temperature of the server system to the BMC;
setting a preset temperature and obtaining the temperature from the temperature sensor by the BMC, and comparing the temperature transmitted by the temperature sensor with the preset temperature;
outputting a first warning signal by the BMC when the temperature transmitted by the temperature sensor is higher than the preset temperature;
outputting a second warning signal by the BMC when the temperature transmitted by the temperature sensor is lower than the preset temperature; and
obtaining the first warning signal and the second warning signal from the BMC by a warning module, and corresponding outputting a first warning information and a second warning information according the first warning signal and the second signal transmitted by the BMC.

6. The control method of claim 5, wherein when the power supply provides power to the server system and the temperature of the system obtained by the BMC is higher than the preset temperature, the BMC outputs a control signal to a PWM control module, the PWM control module obtains the control signal and adjusts the speed of a fan according to the control signal transmitted by the BMC.

7. The control method of claim 6, wherein the PWM control module adjusts the ratio of the duty cycle of a pulse signal to the fan to adjust the speed of the fan according to the control signal transmitted by the BMC.
